(19) United States
(12) Patent Application Publication
(10) Pub. No.: US 2013/0099634 A1
(43) Pub. Date: Apr. 25, 2013

(54) HOUSING OF ELECTRONIC DEVICE

(71) Applicants: YEN-WEN WANG, Tu-Cheng (TW); YUAN-MING WANG, Shenzhen City (CN); BAO-GANG ZHAO, Shenzhen City (CN); PING LI, Shenzhen City (CN)

(72) Inventors: YEN-WEN WANG, Tu-Cheng (TW); YUAN-MING WANG, Shenzhen City (CN); BAO-GANG ZHAO, Shenzhen City (CN); PING LI, Shenzhen City (CN)

(73) Assignees: HON HAI PRECISION INDUSTRY CO., LTD., Tu-Cheng (TW); HONG FU JIN PRECISION INDUSTRY (ShenZhen) CO., LTD., SHENZHEN CITY (CN)

(21) Appl. No.: 13/527,794

(22) Filed: Jun. 20, 2012

(30) Foreign Application Priority Data
Oct. 25, 2011 (CN) 201110327470.5

(51) Int. Cl. H05K 5/02

(52) U.S. Cl. 312/223.1

(57) ABSTRACT

A housing of an electronic device includes a first plate and a second plate detachably secured to the first plate. The first plate defines a latching hole and has an elastic cantilever defining a through hole. The second plate has a protrusion corresponding to the through hole and a latching member corresponding to the latching hole and capable of sliding along the latching hole between an unlatched position disengaging with the latching hole and a latched position engaging with the latching hole. When sliding to the latching position, the latching member engages with the latching hole to prevent the second plate from moving in a first direction, the elastic cantilever elastically deforms to allow the protrusion to be received and held in the through hole, the protrusion abuts the elastic cantilever to prevent the second plate from moving in a second direction reverse to the first direction.

### BACKGROUND

1. Technical Field

The present disclosure relates to housings of electronic devices, and particularly to a housing of an electronic device having a first plate and a second plate detachably secured to the first plate.

2. Description of Related Art

Many electronic devices, such as DVD players, include a housing and a second plate (such as a decorating plate for decorating the housing) mounted to the housing. The second plate is typically secured to the housing by hot melt. However, the second plate may break during melting, and easily falls off after being secured to the housing by the hot melt.

Therefore, there is room for improvement in the art.

### BRIEF DESCRIPTION OF THE DRAWINGS

Many aspects of the embodiments can be better understood with reference to the following drawings. The components in the drawings are not necessarily drawn to scale, the emphasis instead being placed upon clearly illustrating the principles of the embodiments. Moreover, in the drawings, like reference numerals designate corresponding parts throughout the four views.

FIG. 1 is a partial perspective view of an electronic device having a first plate and a second plate in accordance with an embodiment.

FIG. 2 is a partial perspective view of the first plate of FIG. 1.

FIG. 3 is a partial perspective view of the second plate of FIG. 1.

FIG. 4 is an assembly view showing the second plate being secured to the first plate of the electronic device of FIG. 1.

### DETAILED DESCRIPTION

The disclosure is illustrated by way of example and not by way of limitation in the figures of the accompanying drawings in which like references indicate similar elements. It should be noted that references to “an” or “one” embodiment in this disclosure are not necessarily to the same embodiment, and such references mean at least one.

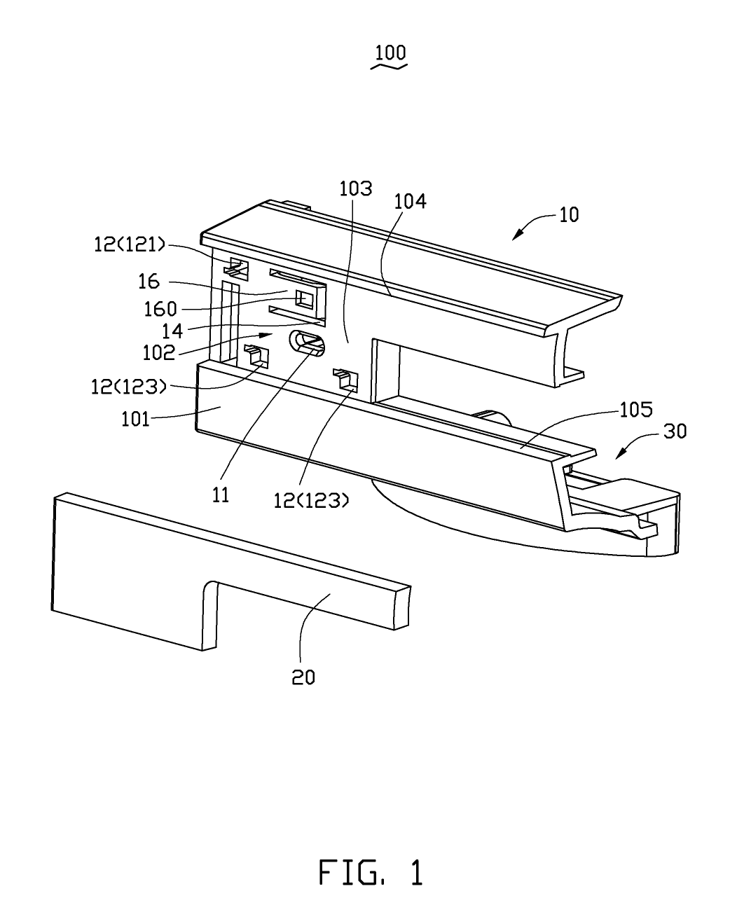

Referring to FIG. 1, an electronic device 100 is shown. The electronic device 100 includes a housing 10. The housing 10 includes a first plate 101 and a second plate 20 detachably secured to the first plate 101. In the embodiment, the electronic device 100 is a DVD player. The first plate 101 is a panel of the electronic device 100 nearest to users, and the second plate 20 functions as a decorating plate for decorating the panel of the housing.

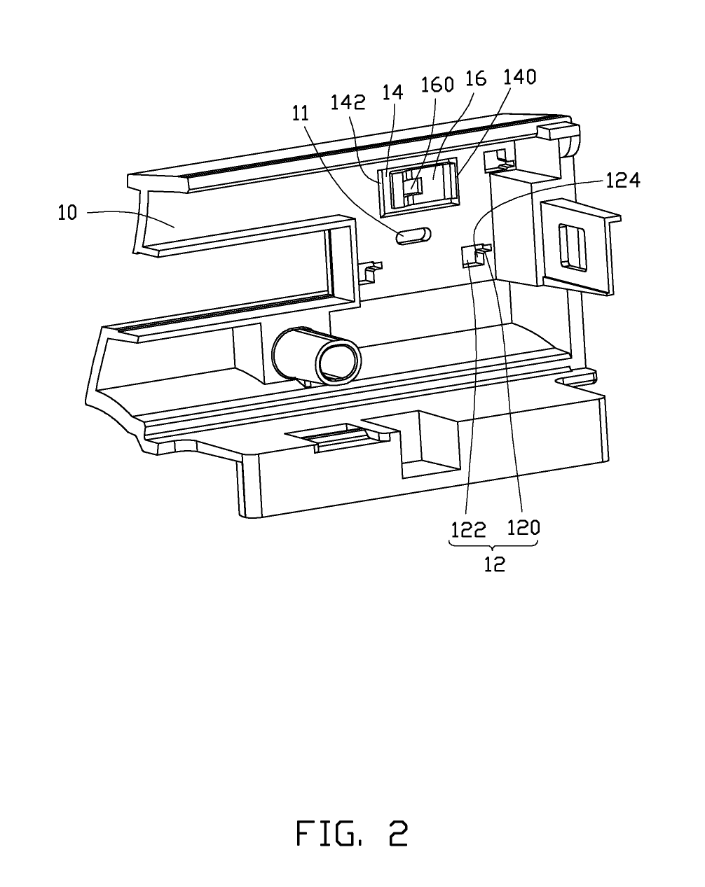

Referring also to FIG. 2, the housing 10 is hollow, and defines a receiving space 30 for receiving a circuit board, a DVD driver, and other electronic components (not shown) of the electronic device 100. The first plate 101 defines a groove 102 for receiving the second plate 20. The size of the groove 102 is substantially equal to the size of the second plate 20, such that the second plate 20 is fitted into the groove 102. The groove 102 includes a bottom wall 103, a first sidewall 104, and a second sidewall 105 opposite to the first sidewall 104. The bottom wall 103 of the groove 102 defines a limiting hole 11, three latching holes 12, and an aperture 14. The limiting hole 11 is substantially elliptical, and communicates with the receiving space 30. The limiting hole 11 is arranged at the middle of the bottom of the groove 102.

The three latching holes 12 communicate with the receiving space 30 and are spaced from each other. One of the latching holes 12 (hereinafter, referred as the first latching hole 121) is arranged adjacent to a first sidewall 104, the other two of the latching holes 12 (hereinafter, referred as the second latching holes 123) are aligned in a line (not shown) parallel to and adjacent to the second sidewall 105. Each latching holes 12 is substantially L-shaped, and includes a latching portion 120 and a guiding portion 122 communicating with the latching portion 120. The width of the latching portion 120 is less than the width of the guiding portion 122. The latching portion 120 cooperates with the guiding portion 122 to form a step 124. The latching portions 120 extend in a direction parallel to the first and second sidewalls 104, 105 and are arranged at the same side of the corresponding guiding portion 122. In the embodiment, when viewed from the front of the housing 10, each latching portion 120 is arranged at a left side of the corresponding guiding portion 122.

The aperture 14 is substantially rectangular, and includes opposite first and second edges 140, 142 perpendicular to the first and second sidewalls 104, 105. An elastic cantilever 16 is secured to the first edge 140 and is parallel to the first and second sidewalls 104, 105. The elastic cantilever 16 is received in the aperture 14 and is coplanar with the bottom wall 103. A free end of the elastic cantilever 16 defines a through hole 160. In the embodiment, the elastic cantilever 16 integrally extends from the bottom wall 103 of the groove 102.

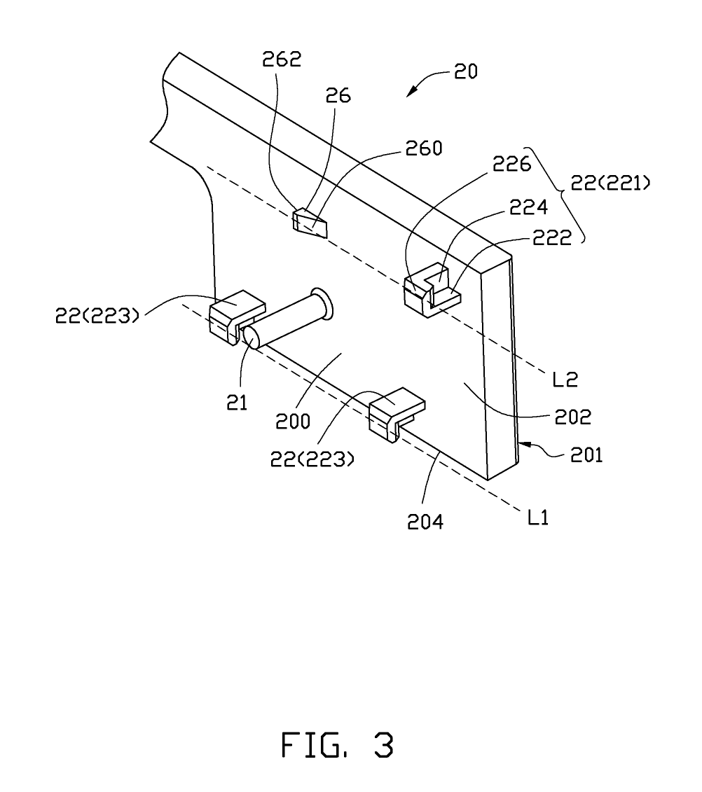

Referring to FIG. 3, the second plate 20 is substantially L-shaped, and includes a front surface 201, a rear surface 202 opposite to the front surface 201, and opposite ends 204. The ends 204 correspond to the first and second sidewalls 104 and 105 respectively. A limiting post 21 protrudes from the rear surface 202 and corresponds to the limiting hole 11.

Three latching members 22 are secured to the rear surface 202. One of the latching member 22 (hereinafter, referred as the first latching member 221) corresponds to the first latching hole 121, and the other two of the latching members 22 (hereinafter, referred as the second latching member 223) correspond to the second latching holes 123 respectively. Each latching member 22 includes a latching plate 222, an abutting plate 224 and a clipping 226. The latching plate 222 perpendicularly protrudes from the rear surface 202 and is parallel to the ends 204. The size of the latching plate 222 is slightly less than the latching portion 120, such that the latching plate 222 is fitted into the latching portion 120. The abutting plate 224 perpendicularly protrudes from the rear surface 202 and perpendicularly connects with the latching plate 222. The abutting plate 224 is perpendicular to the ends 204. The size of the abutting plate 224 is greater than the size of the latching portion 120, such that the abutting plate 224 abuts the step 124 to stop the latching plate 222. The clipping plate 226 interconnects with ends of the first and second holding plates 222, 224 away from the rear surface 102. The clipping plate 226 hooks the step 124 when the latching plate 222 is received in the latching portion 120.

A protrusion 26 is secured to the rear surface 202 and corresponds to the through hole 160. The protrusion 26 and the latching members 22 are arranged surrounding the limiting post 21. In the embodiment, the second latching members 223 are aligned in a first line L1 parallel to the ends 204, and the protrusion 26 and the first latching member 221 are aligned in a second line L2 substantially parallel to the ends 204. The protrusion 26 defines an inclined surface 260 facing the first latching member 221. The inclined surface 260 guides the protrusion 26 to be received in the through hole 160. An end of the protrusion 26 away from the first latching member 221 defines a resisting surface 262 perpendicular to the rear surface 202. The resisting surface 262 abuts the elastic cantilever 16 when the protrusion 26 is received in the through hole 160.

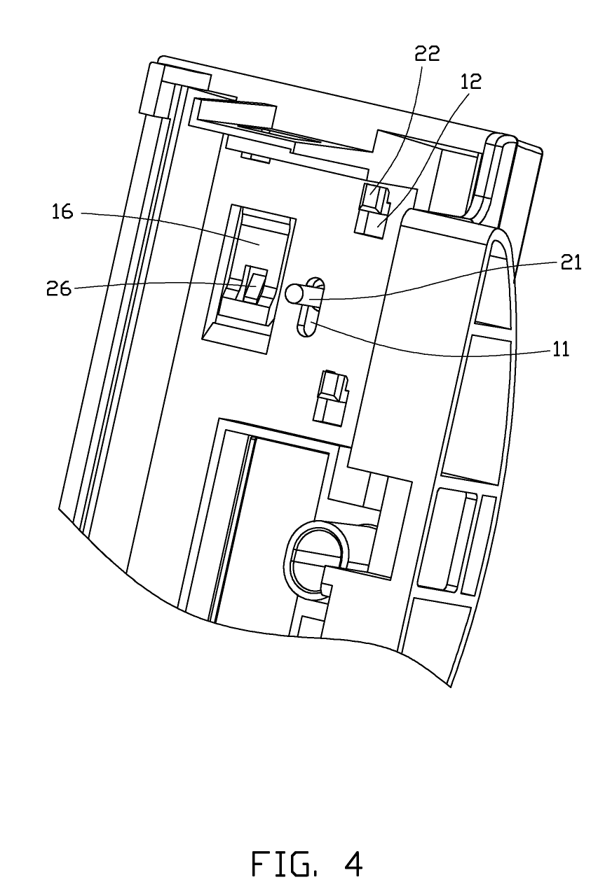

Referring to FIG. 4, to latch the second plate 20 to the first plate 101: firstly, the second plate 20 is received in the groove 102 with the limiting post 21 being received in the limiting hole 11 and the latching members 22 being received in the guiding portions 122 respectively, thus, the second plate 20 is located to and abuts the first plate 101; Secondly, the second plate 20 is driven to slide in a first direction (for example, left), such that the latching plates 222 are received in the latching portions 120 and the clipping plates 226 hook the steps 124 respectively, at the same time, the inclined surface 260 of the protrusion 26 deforms the elastic cantilever 16 and further guides the protrusion 26 to be received in the through hole 160 with the resisting surface 262 abutting the elastic cantilever 16.

After assembly, the clipping plates 226 hook the steps 124, thus the second plate 20 is prevented from moving in a direction perpendicular to the first plate 101. The abutting plates 224 abut the step 124 in the first direction, and the resisting surface 262 of the protrusion 26 abuts the elastic cantilever 16 in a second direction reverse to the first direction simultaneously, thus the second plate 20 is prevented from moving in a direction parallel to the sidewalls 204, 205. Furthermore, the latching portions 222 are received and latched to the latching portions 120 of the latching holes 12, thus the second plate 20 is prevented from moving in a direction perpendicular to the first and second sidewalls 104, 105. Therefore, by means of the latching members 22 and the protrusion 26, the second plate 20 is steadily secured to the first plate 101 of the housing 10.

To unlatch the second plate 20 from the first plate 101: firstly, the elastic cantilever 16 is pressed to allow the protrusion 26 being disengaged therewith; Secondly, the second plate 20 is driven to slide relative to the first plate 101 in the second direction (for example, right) reverse to the first direction, such that the latching plates 222 disengage with the latching portions 120, and the clipping plates 226 disengage with the steps 124. As a result, the second plate 20 is unlatched from the first plate 101 of the housing 10.

It is to be understood, even though information as to, and advantages of, the present embodiments have been set forth in the foregoing description, together with details of the structures and functions of the present embodiments, the disclosure is illustrative only; and that changes may be made in detail, especially in the matters of shape, size, and arrangement of parts within the principles of the present embodiments to the full extent indicated by the broad general meaning of the terms in which the appended claims are expressed.

What is claimed is:

1. A housing of an electronic device, comprising:
a first plate defining at least one latching hole, the first plate having an elastic cantilever defining a through hole; and
a second plate detachably secured to the first plate, the second plate having at least one latching member corresponding to the at least one latching hole, the at least one latching member capable of sliding along the at least one latching hole between an unlatched position disengaging with the at least latching hole and a latched position engaging with the at least one latching hole;
wherein a protrusion protrudes from the second plate and corresponds to the through hole, when the at least one latching member slides to the latching position, the at least one latching member engages with the at least one latching hole to prevent the second plate from moving in a first direction, the elastic cantilever elastically deforms to allow the protrusion to be received and held in the through hole, the protrusion abuts the elastic cantilever to prevent the second plate from moving in a second direction reverse to the first direction.

2. The housing of claim 1, wherein each latching hole comprises a latching portion and a guiding portion communicating with the latching portion, the latching portion cooperates with the guiding portion to form a step.

3. The housing of claim 2, wherein the width of the latching portion is less than the width of the guiding portion.

4. The housing of claim 2, wherein the at least one latching member is latched to the latching portion when sliding to the latching portion, and is received in the guiding portion when sliding to the unlatching portion.

5. The housing of claim 4, wherein each latching member comprises a latching plate, an abutting plate and a clipping plate, the latching plate protrudes from the second plate and extend in a direction parallel to the first direction, the abutting plate protrudes from the second plate and perpendicularly connects with the latching plate, and the clipping plate connects ends of the latching plate and the abutting plate away from the second plate.

6. The housing of claim 5, wherein when the at least one latching member is latched to the at least one latching hole, the latching plate is fitted into the latching portion, the abutting plate abut the step to prevent the second plate from moving in the second direction, and the clipping plate hooks the step to prevent the second plate from moving in a direction perpendicular to the first plate.

7. The housing of claim 5, wherein the size of the latching plate is slightly less than the latching portion, the size of the abutting plate is greater than the size of the latching portion and is slightly less than the size of the guiding portion.

8. The housing of claim 1, wherein the protrusion defines an inclined surface for guiding the protrusion to be received in the through hole.

9. The housing of claim 7, wherein an end of the protrusion away from the inclined surface defines a resisting surface, the resisting surface abuts the elastic cantilever when the protrusion is received in the through hole.

10. The housing of claim 1, wherein the first plate defines a groove for receiving the second plate, the at least one latching hole is defined at the bottom wall of the groove.

11. The housing of claim 10, wherein the bottom wall of the groove further defines an aperture, the elastic cantilever is secured to an edge of the aperture.

12. The housing of claim 11, wherein the elastic cantilever is received in the aperture and is coplanar with the bottom wall of the groove.

13. The housing of claim 1, wherein a limiting post protrude from the second plate, and the first plate further defines a limiting hole corresponding to the limiting post.

14. The housing of claim 13, wherein the limiting post is received in the limiting hole when the second plate is secured to the first plate.
